(19) United States
(12) Patent Application Publication
(10) Pub. No.: US 2012/0268139 A1
(43) Pub. Date: Oct. 25, 2012

(54) DEVICE FOR DETECTING A LEVEL

(76) Inventors: Peter Fend, Memmingen (DE); Alexander Martens, Memmingen (DE); Erwin Steinle, Lautrach (DE)

(21) Appl. No.: 13/518,815

(22) PCT Filed: Nov. 29, 2010
(86) PCT No.: PCT/EP2010/068387

§ 371 Date: Jul. 11, 2012

(30) Foreign Application Priority Data
Dec. 30, 2009 (DE) 10 2009 060 742.0

(51) Int. Cl. G01R 35/00; G01R 27/26; G01R 27/28

(52) U.S. Cl. 324/601; 324/649; 324/658

(57) ABSTRACT

In order to provide a device (1) for detecting a level (3) of media (4), preferably in a tank (2, 200), comprising an elongate electrical probe conductor (6) projecting substantially vertically into the tank (2, 200), which can be attached in a manner electrically insulated from said tank, a electrical time-variable generator (7) having an internal impedance (Zg) for connection to a feed point (11) of the probe conductor (6) in order to apply a time-variable voltage to this, wherein the feed point (11) is disposed on one, preferably on the tank-side, end of the probe conductor (6), and an evaluation and/or control unit (9) for evaluating an electrical quantity of the probe conductor (6), which can detect a level of any media, in particular liquid, pasty and/or granular solid media, in the simplest possible, error-tolerant and cost-effective manner, it is proposed that the evaluation and/or control unit (9) is configured to measure a base impedance of the probe conductor (6) at the feed point (11).

The present invention relates to a device for detecting a level of media, preferably in a tank, comprising an elongate electrical probe conductor projecting substantially vertically into the tank, which can be attached in a manner electrically insulated from said tank, a electrical time-variable generator having an internal impedance (Zg) for connection to a feed point of a probe conductor in order to apply a time-variable voltage to this, where the feed point is disposed on one, preferably on the tank-side, end of the probe conductor, and an evaluation and/or control unit for evaluating an electrical quantity of the probe conductor.

The invention further relates to a method for operating a device according to any one of claims 1 to 13 for the measurement of a level.

The present invention further relates to a method for calibrating, in particular after variation of the probe conductor, a device according to any one of claims 1 to 13.

Finally the invention relates to a use of a device according to any one of claims 1-13.

Generic devices as well as methods for operating the same are known in various designs. The known devices and methods are based, for example, in conductive methods on the evaluation of the electrical conductance. On the other hand, in known capacitive devices and methods, the measurement is based on the evaluation of an electrical capacity.

A disadvantage with the known methods is in particular the dependence on properties of the medium, whose level is to be measured. In particular, in the known methods the relative dielectricity or the specific electrical conductance needs to be taken account in the evaluation. In addition, some of the previously known measuring devices are disadvantageously only suitable for electrically conducting media. Furthermore, the known measuring devices are disadvantageously susceptible to perturbing influences such as foam formation and deposit build-ups. Hence, a sensitivity adjustment involving an adaptation to the medium to be detected is usually required. In the known devices this is frequently difficult or even impossible if different media are used successively in the same application. In the known conductive method, attempts have certainly been made to keep the effective electrode area constant with rising foam by means of a partial insulation from the upper region by lengthening the path distance of conducting bridge formations in adhesive media. However, an insulation coating disadvantageously increase the costs.

Previously known from the documents DE7933089U1, DE8018675U1 and DE102005025576A1 are various embodiments of capacitive measuring probes for the measurement of filling level. With capacitive measurement probes, there is also the problem that these frequently fail accompanying foam formation. In addition, with these probes an insulating coating disadvantageously increases manufacturing costs and causes problems due to diffusion effects, in particular in applications at high temperatures.

Furthermore, transit time methods are known such as, for example, pulse transit time measurement, time domain reflection (TDFR), guided radar echo methods, which do not necessarily require electrical insulation of the probe conductor but are disadvantageous in relation to the relatively high expenditure involved in interpreting the trigger and evaluation circuits for a very high frequency range.

Against this background, it is the object of the present invention to provide a device of the type mentioned initially which can detect a level of any media, in particular liquid, pasty and/or granular solid media, in the simplest possible, error-tolerant and cost-effective manner.

It is further the object of the present invention to provide a corresponding method for operating and a use of a device of the type specified initially which obviate the shortcomings of the known devices.

It is further the object of the present invention to provide a method for calibrating, in particular after variation of the probe conductor, of such a device which is easy to use in order to apply the device flexibly under different measurement conditions and to different probe conductors.

According to the invention, the object directed towards a device is solved with a generic device for detecting a level in which the evaluation and/or control unit is configured to measure a base impedance of the probe conductor at the feed point. Within the framework of the invention, the voltage can be applied on the one hand at the tank-side end of the probe conductor. This is expedient if the probe conductor projects from above into the tank. In certain designs, when the level falls below a certain value in this structure, the probe conductor may not be in contact with the medium. Alternatively, within the framework of the invention, the voltage can be applied to the end of the probe conductor which projects into the tank. This is expedient if the probe conductor projects into the tank from below so that with increasing filling level, a decreasing length section projects beyond the medium. In this configuration, the wiring and evaluation of the device is in each case accomplished complementary to the design in which the probe conductor projects from above into the tank.

In one embodiment of the invention, it is provided that the generator comprises an electrical oscillator in order to apply an alternating voltage having a pre-definable frequency to the feed point. In this way, resonance phenomena can be determined according to the invention by measurement of the base impedance which according to experimental findings, are influenced by whether, and if appropriate how deeply, the measurement probe is immersed in the medium.

In a preferred embodiment of the invention, it is provided that the oscillator is configured to generate an alternating voltage with a resonance frequency of the circuit formed from the probe conductor, the oscillator and the tank and/or the counter-conductor, where the evaluation and/or control unit is configured to measure a base impedance of the probe conductor at the feed point. The observed dependence of the base impedance on the immersion state of the probe is particularly marked at this frequency.

In particular, according to the invention the oscillator can be configured to generate an alternating voltage having a λ/4 frequency, which substantially corresponds to a wavelength which is four times the length extension of the probe conductor. With regard to this frequency, it was observed according to the invention that the amplitude thereof changes abruptly upon immersion of the probe in the medium.

The oscillator can be configured to generate an alternating voltage having a quarter-wave frequency, which substantially corresponds to a wavelength having four times the length extension of the probe conductor, where the evaluation and/or control unit is configured to measure a base impedance of the probe conductor at the feed point. This structure according to the invention advantageously enables the immersion of the probe conductor into the medium to be determined reliably and in an error-tolerant manner, in particular independently of the medium, on the basis of a strong shift of the resonance frequency of the circuit formed from the probe conductor and a counterweight, which can be observed upon immersion of the end of the probe conductor opposite to the feed point. A threshold-value evaluation of the resonance amplitude at a quarter of the wavelength within an evaluation window in the frequency and amplitude axis by evaluation of the base impedance thus allows a reliable determination of the state “not immersed” or “immersed”. When the end of the probe conductor opposite to the feed point contacts the medium, the base impedance at the quarter-wave frequency increases so strongly within the evaluation window that with a suitable choice of evaluation window, the impedance value lie outside this evaluation window. Hence, in particular a reliable determination can advantageously be made using devices according to the invention as to whether a level of a medium has reached a certain value or not. Since the determination of the limit level is only made on the basis of the frequency position of the minimum point in a relatively large evaluation window, according to the invention a detection can advantageously be made for almost all media used industrially without an adapted adjustment of a threshold to the medium with a large safety margin. It was observed that the abrupt change in the resonance frequency when the end of the probe conductor opposite the feed point comes in contact with the medium occurs largely independently of the properties of the medium. It was also observed that the threshold value evaluation is advantageously not critical to tolerances and drifts in the evaluation electronics of the available components. It was also observed that the level measurement made with the device according to the invention is not falsified by foam formation. Also bridge-forming deposit build-ups, in particular of pasty media, between the tank-side feed point of the probe conductor and, for example, the tank wall have advantageously also not falsified the level measurement. The observed advantages of the device according to the invention can possibly be explained by the theory of a quarter-wave dipole as which the electrical probe conductor according to the invention functions. On contact of the electrical probe conductor with the medium, according to this theory, a so-called top-loading capacitance at the interface between air and the medium to be detected is added to the circuit, which brings about the observed frequency shift.

If in one embodiment of the invention, the oscillator is additionally configured for electrical connection to the tank, the tank can advantageously take over the function of the opposite pole, called counterweight, on which the probe conductor is mirrored electrically. The circuit formed from the probe conductor and the tank then corresponds according to the invention to a half-wave dipole. A prerequisite for this embodiment of the invention is naturally that the tank is electrically conducting.

If, according to another advantageous embodiment of the invention, the generator comprises a pulse generator for generating control pulses, where the evaluation and/or control unit is configured for the frequency-resolved measurement of the base impedance of the probe conductor at the feed point, the device according to the invention can be operated in a burst mode. In this case, so-called bursts, that is wave packets having a predefined oscillation frequency, are generated, whereby the pulse generator is operated for switching on and off an oscillator by means of control pulses. It is expedient within the framework of the invention if the oscillation frequency within the burst is different in each case. Then an evaluation of the impedance can be made with every burst in order to thus scan the frequency spectrum of the measurement arrangement in discrete frequency steps. The scanning rate required for the evaluation in this method can advantageously be selected to be low since a quasi-stationary state is established within each burst. Since, according to this variant of the invention, a high-frequency voltage is not applied continuously to the system but only within the bursts, the device can advantageously be operated in an EMC compatible manner. In addition, advantages are obtained with regard to the energy consumption of the device according to the invention.

A different evaluation of the filling level is possible with another advantageous embodiment of the invention in which the generator comprises a pulse generator for generating excitation pulses, where the excitation pulses have at least one flank increasing to a maximum within a time interval corresponding to the order of magnitude of the reciprocal of a highest frequency to be evaluated. With this arrangement according to the invention, a jump response of the system can be determined and evaluated. For example, a fast Fourier transformation (FFT) can be performed in order to evaluate the frequency spectrum of the jump response. In order to reduce the scanning rates required for the evaluation of a jump response during the signal recording, within the framework of the invention, the evaluation can also be made by the so-called sampling method. This is familiar to the relevant person skilled in the art, for example, from the operating mode of sampling oscilloscopes. For this purpose, a so-called “undersampling” is carried out for the evaluation, that is a scanning at a lower frequency than the frequency to be measured, by slightly shifting the scanning time in each pulse period.

In another advantageous embodiment of the invention, it is provided that in addition to the probe conductor, an electrical counter-conductor is provided to form an electrical opposite pole, where the oscillator is additionally configured for electrical connection to the counter-conductor. According to this advantageous variant of the invention, the measuring device according to the invention can also be used to determine levels in tanks made of a non-conducting material. The electrical counter-conductor then functions as opposite pole/counter-weight at which the probe conductor is mirrored electrically in order to overall reconfigure a half-wave dipole. Along with the application of the device according to the invention in non-conductive tanks, this configuration advantageously even enables the measuring device to be used in the open.

In a special embodiment of the invention, the counter conductor is configured to be disposed inside the tank, preferably parallel to the probe conductor. The spatial accommodation of the counter-conductor in this manner advantageously presents no problems.

If the counter-conductor is configured to be substantially of the same type as the probe conductor, the behaviour of a Lecher line can be seen in a suitable arrangement of the counter-conductor relative to the probe conductor according to the invention.

In particular, in a preferred embodiment of the invention, the counter-conductor can be configured as an open strip transmission line and therefore as a waveguide.

In a preferred embodiment of the invention, the probe conductor can be rod-shaped and/or shaped as a cable. For example, mechanical components already present in a tank can be used in order to cooperate in combination with the other features of the invention for the device according to the invention. In particular, for example, the probe tube used for the potentiometric measurement from DE 272 3 999 C2 can be used as a probe conductor of the device according to the invention. The configuration of the probe conductor according to the invention as a rod and/or as a cable additionally enables the length to be easily adapted to the variation in the limit level to be detected.

In a further advantageous embodiment of the invention it is provided that a variable impedance is switched between the evaluation and/or control unit and a circuit formed from the probe conductor, the oscillator and the tank and/or the counter-conductor. This variable impedance advantageously enables the measuring device to be adapted to different measurement conditions with regard to length of the probe conductor, oscillator frequency and the evaluation and/or control device used. According to the invention, the variable frequency is used to increase the depth of the resonance points which are important for the evaluation, in particular the resonance minima, to facilitate the evaluation in the sense of increasing the contrast. This can be achieved, for example, as is familiar to the person skilled in the art by selecting a high-resistance impedance in combination with a following amplifier having a correspondingly high amplification factor.

A particularly versatile embodiment of the device according to the invention provides means for pulsed triggering of the oscillator and/or for, preferably continuous, variation of the frequency within a frequency interval, where the oscillator is preferably configured for generating frequencies in a range around three times and/or five times the λ/4 frequency and/or twice and/or four times the λ/4 frequency. Both the pulsed triggering and also a continuous variation of the frequency in the sense of a frequency sweep advantageously make it possible to record a frequency spectrum, i.e. the base impedance as a function of the oscillator frequency. By means of an evaluation of the frequency spectrum in the frequency range of ¾ and 5/4 of the wavelength, in addition to the above-described use of the device according to the invention as a limit level monitor, a continuous determination of the level can advantageously be carried out. To this end, use is made of the experimentally observed shift of the impedance minimum to higher frequencies with increasing immersion depth in the medium. A possible explanation for this experimentally observed behaviour could be a shortening of the oscillation length of the section of the probe conductor located outside the medium.

Similarly, within the framework of the invention, an evaluation of the measured values can be made at even-numbered multiples of the quarter-wave frequency, corresponding to an evaluation at the maximum points of the base impedance.

In order to reduce the scanning rates required for the evaluation of the resonance spectra and thus keep the costs for the corresponding components low, within the framework of the invention the evaluation can also be made according to the so-called sampling method as is familiar to the relevant person skilled in the art, for example, from the operating mode of sampling oscilloscopes, then a so-called “undersampling” is carried out, that is, a scanning at lower frequency than the frequency to be measured, by shifting the scanning time slightly for each pulse period. This operating mode is therefore in principle based according to the invention on the fact that two oscillators having slightly different but in each case constant frequency are present in the control unit, where the excitation pulses are obtained from the one oscillator by appropriate frequency splitting and the scanning pulses are obtained accordingly from the other oscillator. This form of evaluation is also familiar to the person skilled in the art in its own right.

The object directed towards a method for operating a device according to any one of claims 1 to 14, forming the basis of the present invention is solved in a generic method for measuring the base impedance by measuring the oscillation amplitude at at least one frequency in order to determine the level. In particular, the measurement of the oscillation amplitude at the said quarter-wave frequency allows the method to be used as a limit level monitor since it was observed experimentally that the impedance on contact of the end of the probe conductor opposite the feed point is significantly higher than when the probe conductor does not contact the medium. Also, according to the method according to the invention, the oscillation amplitude can be measured at a frequency which corresponds to three times and/or five times the quarter-wave frequency in order to determine changes in the filling level since it was observed experimentally that at the last-mentioned frequencies, changes in the filling level lead to changes in the base impedance.

In particular, in one embodiment of the method according to the invention, the oscillation amplitude can be measured at a reference frequency, where a signal is generated when a pre-selected value of the oscillation amplitude is exceeded. For example, the quarter-wave frequency can be used as a reference frequency, which, according to experimental findings, is lower when the end of the probe conductor opposite the feed point is in contact with the medium than when the probe conductor is not in contact with the medium. According to this embodiment of the method according to the invention, it is therefore sufficient if a relatively narrow-band frequency window is evaluated where merely the exceeding or falling below a threshold value is determined in the evaluation.

If in a special embodiment of the method according to the invention, the reference frequency is the quarter-wave frequency and/or an odd integral multiple of the quarter-wave frequency, the method according to the invention is used to employ the device according to the invention as a limit level monitor, where at the same time changes in the oscillation amplitude, for example, at three times the quarter-wave frequency and/or five times the quarter-wave frequency can be determined to detect different levels when a probe conductor is immersed in the medium.

A particularly advantageous embodiment of the method according to the invention for operating the device provides that the oscillator is operated successively at different frequencies, where the oscillation amplitude is measured and recorded and that in the frequency spectrum emitted in such a manner, the frequency position of at least one amplitude minimum is determined. For example, a frequency sweep can be performed in which the oscillator is operated, in the favourable case, continuously at frequencies from below the quarter-wave frequency up to values in the range of five times the quarter-wave frequency whilst simultaneously recording the corresponding impedance values.

With the aid of the evaluation and control unit, a limit level monitor function can be performed according to the invention by reference to the recorded spectrum by evaluation within an evaluation window which is located in the frequency axis in a range around the quarter-wave frequency and detects a range about a pre-selected threshold value in the amplitude axis. Furthermore, in the event that the signal runs out from the evaluation window for the limit level monitoring, frequencies, in particular minimum points in the range of three times and/or five times a quarter-wave frequency whose amplitudes vary with changes in the state according to experimental observation are evaluated as evidence for the immersion of the probe conductor. In addition, it was observed experimentally that the amplitude minima are shifted on the frequency axis as a function of the immersion depth of the probe conductor. In this case, an increase in the immersion depth leads to a shift of the minimum, that is, of the resonance frequencies, to higher frequencies and conversely. The evaluation of the positions of the amplitude minima is therefore also used according to the invention as a measure for the level height if it is ascertained by the signal running outside the evaluation window that the probe conductor contacts the medium or is immersed in this.

If in a favourable embodiment of the invention, control pulses are generated by means of the generator, the method described above can be carried out according to the invention to produce bursts each having a different oscillation frequency. To this end, the frequency is preferably varied accordingly in each burst. By means of this method, the required high-frequency irradiation EMC limits can advantageously be adhered to particularly easily by reducing the power. This additionally has an advantageous effect due to a reduced energy requirement of the trigger unit.

According to another advantageous embodiment of the method according to the invention, excitation pulses are generated by means of the generator, where the excitation pulses have at least one flank increasing to a maximum within a time interval corresponding to the order of magnitude of the reciprocal of a highest frequency to be evaluated. Frequency spectra can also be evaluated by this means on the basis of the known phenomenon of wave mechanics. To this end, in order to reduce the required scanning rate, the above-described sampling method can be used.

In a preferred embodiment of the method according to the invention, the frequency position is used to determine the level. According to the invention, the experimentally observed phenomenon is therefore advantageously used whereby the position of the amplitude minima in particular in the range of three times and/or five times that of a quarter-wave frequency is shifted to higher frequencies with increasing immersion depth, corresponding to decreasing non-immersed length of the probe conductor from a minimum immersion depth of the probe conductor in the medium.

According to another advantageous further development of the method according to the invention for operating the device, the quality of at least one amplitude minimum is determined in order to make a determination of an appertaining resonance order to determine the level. It has been observed that in certain arrangements an overlap of different frequency spectra occurs in such a manner that, for example, an amplitude minimum shifted to higher frequencies coincides with a higher-order amplitude minimum that is barely frequency-shifted or not at all frequency-shifted. In the course of the evaluation, this could have the result that a determined amplitude minimum is incorrectly interpreted as a shifted amplitude minimum according to a three-quarter wavelength resonance as a result of immersion of the probe conductor in the medium although this actually comprises a five-quarter wavelength resonance minimum as a result of a lower immersion depth since it was observed experimentally that the quality, that is the ratio between the frequency at the minimum to the frequency width of this minimum varies according to the resonance order. Accordingly, the evaluation of the quality proposed according to the invention here serves as an additional distinguishing criterion.

Within the framework of the method according to the invention, a three-quarter-wave resonance is located as follows: firstly it is determined whether a minimum is present at the resonance frequency or within the evaluation window. Then, if it has been determined that no minimum is present in the first step, the first minimum, that is the minimum at the lowest frequency position above the reference frequency, is determined in the second step. This is the three-quarter-wave resonance according to the experimental findings.

In a further advantageous embodiment of the method according to the invention for operating a device, the frequency interval includes three times and/or five times the quarter-wave frequency. In this way, in particular, a frequency shift of amplitude minima in this frequency range can advantageously be evaluated as a measure for the immersion depth of the probe conductor when the probe conductor is immersed, that is in the event that a threshold value evaluation in the range of the quarter-wave frequency shows that the probe conductor is immersed in the medium.

The object directed towards a method for calibrating, forming the basis of the invention is solved in such a method whereby a frequency spectrum of the circuit formed from the probe conductor, the generator and the tank and/or the counter-conductor is recorded, where the probe conductor is not in contact with media during the recording and that the frequency position of at least one amplitude minimum is determined in the frequency spectrum. It is thus provided according to the invention to record the frequency spectrum when the probe conductor is not immersed in the medium in order to determine the positions of the quarter-wave frequency as well as higher-order resonances, in particular of three times and/or five times the quarter-wave frequency. The further calibration can be performed by reference to the information about the frequency position of the amplitude minima, whereby the first minimum located, that is that which occurs at the lowest frequency, is identified with the quarter-wave frequency. An evaluation window is then placed around this minimum according to the invention, in order to use the device according to the invention as a limit level monitor using the method specified above. The amplitude minima following the first minimum, which were determined by the method for calibrating according to the invention give the evaluation points for a continuous determination of the immersion depth for the case of a probe conductor immersed in the medium. With the calibrating method according to the invention, a measuring device according to the invention can advantageously be used in tanks with existing electrodes without, for example, a length measurement of the electrode being required. The calibration can also be made in the manner described after the probe conductor has been shortened or, for example, by welding on, lengthened in order to detect another limit level. The calibration is advantageously largely independent of the medium used. In particular, it need not be carried out when a pure change of media inside the tank is made. This is because, as was found experimentally, the method according to the invention is primarily dependent on the length of the probe conductor and in particular substantially not on the media properties.

In one embodiment of the method for calibrating in order to record the frequency spectrum, the generator is successively operated at different frequencies, where the oscillation amplitude is measured and recorded.

In an advantageous embodiment of the method for calibrating according to the invention, in order to record the frequency spectrum, control pulses are generated by means of the generator.

An advantageous embodiment of the method for calibrating provides that excitation pulses are generated by means of the generator where the excitation pulses have at least one flank increasing to a maximum within a time interval corresponding to the order of magnitude of the reciprocal of a highest frequency to be evaluated. The pulse triggering is particularly favourable with regard to adhering to the required high-frequency irradiation EMC limits as a result of the reduction in power. As a result of the broadening of the frequency spectrum accompanying a reduction in the temporal width of a pulse due to the wave mechanics, with a suitable evaluation, a frequency spectrum is also recorded as a result with the excitation pulse operation.

The object directed towards a use of a device according to any one of claims 1 to 15, forming the basis of the invention is solved with such a method in which in parallel the same level of the same medium is measured by means of a potentiometric and/or capacitive and/or echo method. The advantage of the parallel implementation according to the invention of measurements based on different measurement principles is an increase in the operating safety due to the redundancy thus obtained. In particular, it is advantageous within the framework of the invention if the measuring device according to the invention is used together with measurements whose evaluation is media-dependent unlike the invention and/or if additional information is required as to whether the probe conductor is immersed in the medium at all.

The invention is described in a preferred embodiment with reference to the drawings as an example, where further advantageous details can be deduced from the figures in the drawings.

Parts having the same function are provided with the same reference numbers.

In detail, in the figures in the drawings:

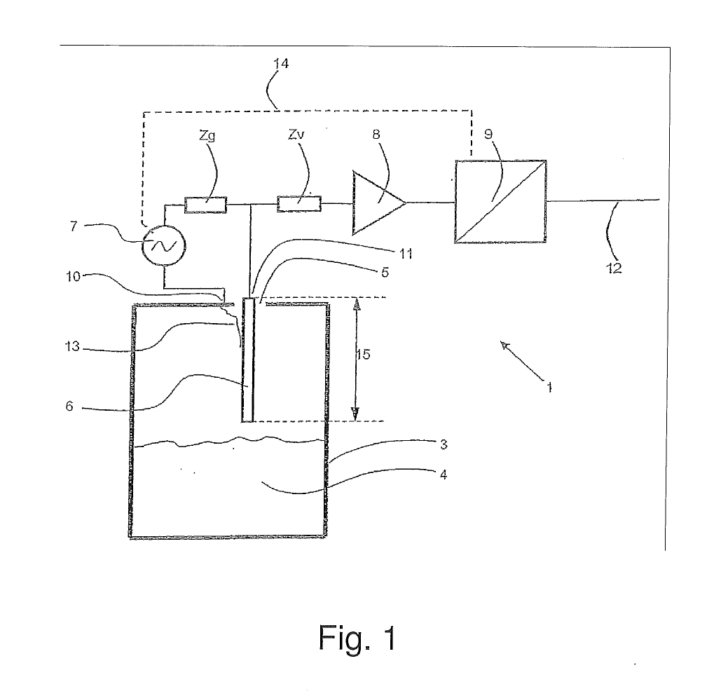

FIG. 1: shows a schematic view of a first embodiment of the measuring device according to the invention used on an electrically conducting tank;

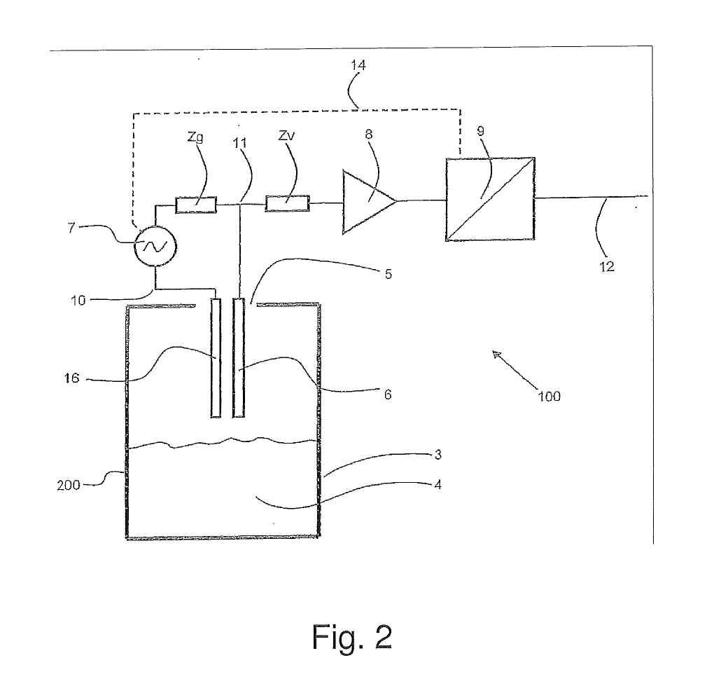

FIG. 2: shows a schematic view of another embodiment of the measuring device according to the invention used on an electrically non-conducting tank;

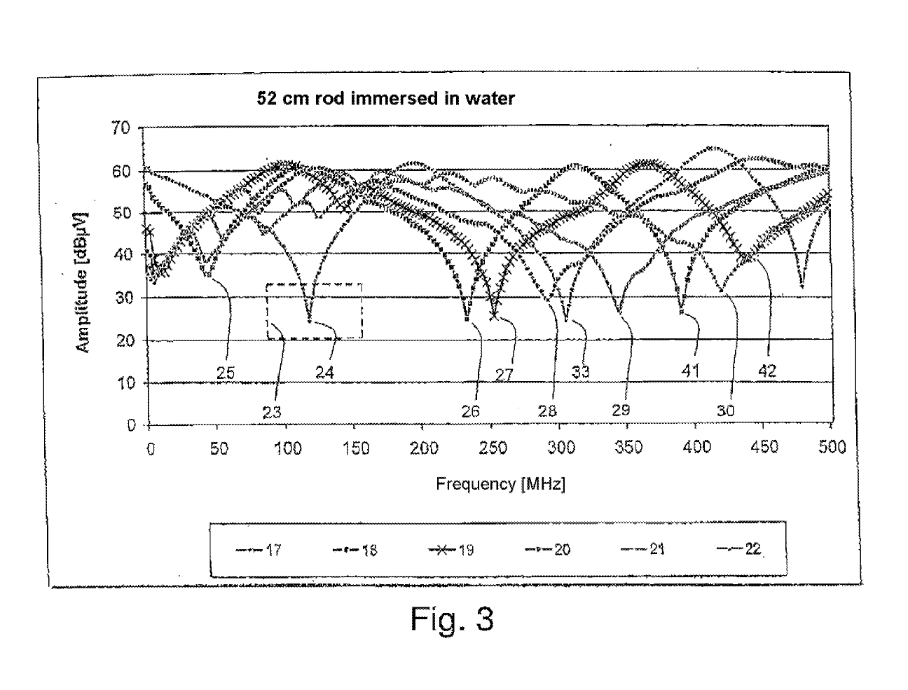

FIG. 3: shows schematic frequency spectra to explain the method for operating the measuring devices according to FIG. 1 and/or FIG. 2;

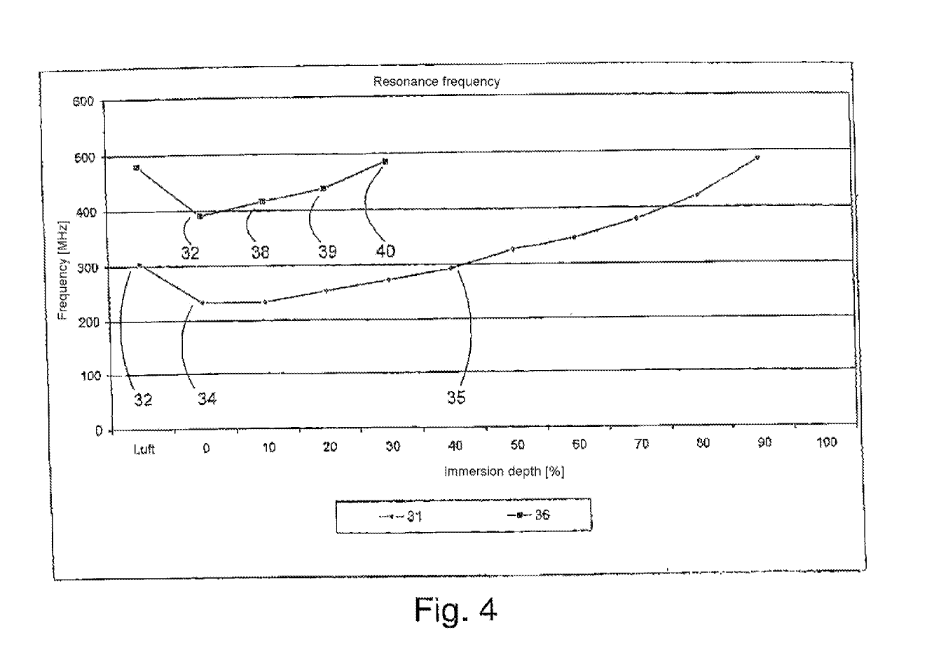

FIG. 4: shows a schematic view of the position of amplitude minima as a function of the immersion depth of the probe conductor of a measuring device according to the invention to illustrate the method according to the invention for operating the same;

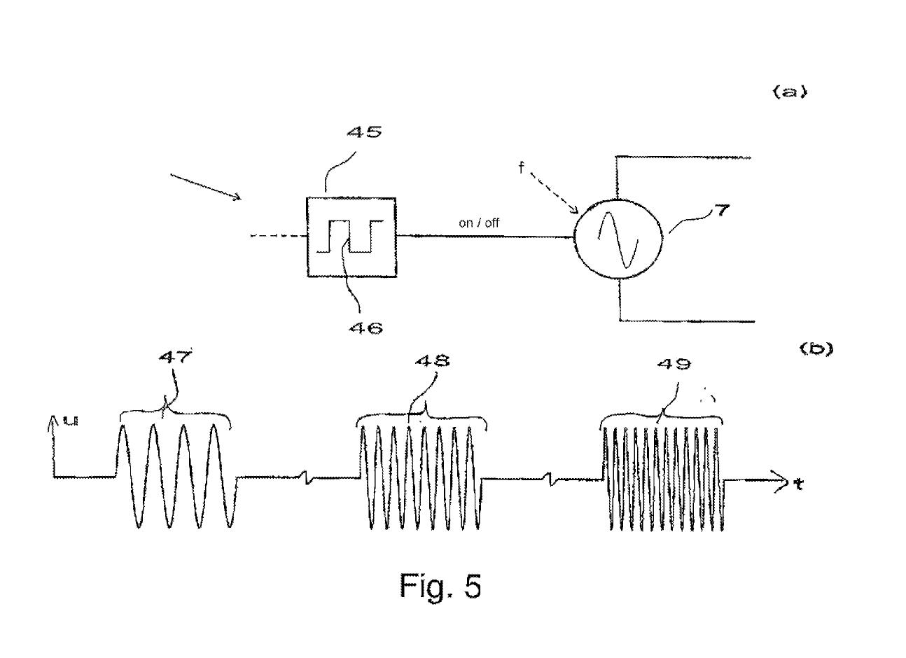

FIG. 5: shows a schematic circuit diagram (a) and a signal time profile (b) to illustrate a preferred embodiment of the invention.

FIG. 1 shows schematically a level measuring device 1 according to the invention used on a tank 2. The tank 2 is made of an electrically conducting material and is filled with a medium 4 as far as a level 3. The medium 4 can be any in particular liquid, pasty and/or granulated solid medium.

The electrically conducting tank 2 has an opening 5 on the upper side. Through the opening 5 in the electrically conducting tank 2, a probe electrode 6 is inserted into the electrically conducting tank 2 in such a manner that the probe electrode 6 is electrically insulated from this. The level measuring device 1 substantially consists of the probe electrode 6 introduced in the manner described into the electrically conducting tank 2, an oscillator 7, an amplifier 8 and of an evaluation and control unit 9.

According to the design outlined in FIG. 1, one terminal 10 of the oscillator 7 is connected to the electrically conducting tank 2 and the other terminal 11 is connected to the probe electrode 6. In the schematic view according to FIG. 1, the electrical relationships are shown substantially as an equivalent circuit diagram, where an internal impedance Zg of the oscillator 7 is shown schematically at the terminal 11. The terminal 11 corresponds to the feed point of the probe electrode 6. The evaluation and control unit 9 is connected via the amplifier 8 and the amplifier impedance Zv shown schematically in the equivalent circuit diagram to the feed point 11 of the probe electrode 6. An output signal 12 of the evaluation and control unit 9 is suitable for being fed to a display unit to display a level.

The schematic diagram further shows a deposit build-up 13 which forms a bridge between the end of the probe electrode 6 facing the opening 5 of the tank 2 and the tank wall 2. It has been found experimentally that such an adhesive deposit 13 substantially has no effects on the measurement result so that the level 3 can be reliably determined despite the deposit build-up 13.

The evaluation and control unit 9 is further configured to trigger the oscillator 7. This is indicated in the schematic diagram by the dashed signal line 14. The oscillator 7 can be operated at frequencies in a continuously tunable manner in a frequency spectrum extending at least as far as the quarter-wave frequency. The probe electrode 6 has a length 15.

FIG. 2 shows an alternative embodiment of a level measuring device 100 according to the invention. The level measuring device 100 has substantially the same structure as the level measuring device 1 according to FIG. 1. The schematic FIG. 2 shows the level measuring device 100 in use on an electrically non-conducting tank 200.

Unlike the level measuring device 1 shown in FIG. 1, the level measuring device 100 shown in FIG. 2 has a counter-electrode 16. The counter-electrode 16 is attached parallel to the probe electrode 6 through the opening 5 in the tank 200. Unlike the situation shown in FIG. 1, the terminal 10 of the oscillator 7 is not connected to the tank 200 but to the counter-electrode 16. Otherwise, the components and the arrangement thereof corresponds to the level measuring device 1 explained in relation to FIG. 1.

The method explained hereinafter is used in each case to operate the level measuring device 1 to carry out measurements of the level 3 in the tank 2 and equally to operate the level measuring device 100 to measure the level 3 in an electrically non-conductive tank 200.

The oscillator 7 is triggered with the aid of the evaluation and control unit 9 via the control signal line 14 in order to run continuously at frequencies between 0 and 500 MHz. At each frequency, the oscillation amplitude is determined and stored in the evaluation and control unit 9.

The frequency range of 0 to 500 MHz selected in the exemplary embodiment for the frequency sweep is suitable according to the invention for a probe electrode 6 having a length 15 of the order of magnitude of 50 cm. It has been shown that the choice of this frequency range enables the level measurement to be made according to the invention with rod lengths of only up to about 20 cm. However, it is equally possible within the framework of the invention to select rod lengths of only a few millimetres, for example, if the evaluated and excited frequency interval is correspondingly increased.

Then, one of the frequency spectra depicted graphically in FIG. 3 is stored in the evaluation and control unit 9. The graphical diagram according to FIG. 3 shows respectively one frequency spectrum, that is one measured amplitude of the base impedance of the probe conductor 6. Here, curve 17 shows the frequency profile for a probe electrode 6 not immersed in the medium 4. Curve 18 shows the frequency spectrum obtained when the end of the probe electrode 6 opposite the feed point 11 is located at the height of the level 3 and therefore just contacts the medium 4. Curve 19 shows the frequency spectrum for the case where the probe electrode 6 is immersed in the medium 4 with 20% of its length 15. Accordingly, curves 20, 21, 22 show the frequency spectra for immersion depths of 40%, 60% or 80% of the length 15 of the counter-electrode 16 in the medium 4.

FIG. 3 further illustrates the evaluation window 23 used to evaluate the measurement result of the frequency sweep from 0 to 500 MHz. As can be seen, the evaluation window 23 encloses a frequency range of about 50 MHz around a first amplitude minimum 24 of the frequency spectrum 17. In the vertical direction, the evaluation window 23 encloses an amplitude range which encloses the amplitude value at the amplitude minimum 24 of the dry curve 17.

In order to use the measuring device according to the invention as shown in one of FIG. 1 or 2 according to the method according to the invention as a limit level monitor, a frequency sweep is carried out at regular intervals—or also continuously—with the oscillator 7 which at least encloses the horizontal extension of the evaluation window 23. It is then determined whether the amplitude of the measuring signal is within the evaluation window 23. If this is the case, it is concluded from this in the evaluation and control unit 9 that the level 3 is located below the probe electrode 6 so that the probe electrode 6 does not contact the medium 4. Accordingly, the frequency curve 17 is obtained.

As soon as the probe electrode 6 contacts the medium 4, the frequency sweep gives the curve 18 which in particular is characterised in that its first amplitude maximum 25 is shifted so strongly towards the amplitude minimum 24 of the dry curve 17 that it lies outside the evaluation window 23. From this it is concluded in the evaluation and control unit 9 that the threshold level is reached and a corresponding output signal 12 is generated. As can be seen from FIG. 3, the first amplitude minima of the frequency spectra 19, 20, 21, 22 for successive increasing immersion depths of the probe electrode 6 in the medium 4 also lie significantly outside the evaluation window 23. The amplitude minimum 24 of the dry curve 17 therefore falls within the evaluation window 23 as the only one of the curves 17, 18, 19, 20, 21, 22. The function of a limit level monitor can thus be achieved by the method according to the invention.

Furthermore, a continuous determination of the level 3 can be made by the method according to the invention subject to the requirement that the end of the probe electrode 6 opposite the feed point 11 at least contacts the medium 4 or projects into this with a part of its length 15. Therefore, if no signal can be determined within the evaluation window 23, an evaluation of the second amplitude minima of the curves 18, 19, 20, 21, 22 yields a measure for the degree of the immersion depth of the probe of the electrode 6 into the medium 4.

To this end, it can be identified in FIG. 3 that according to experimental observation the second amplitude minima 26, 27, 28, 29, 30 of the frequency spectra 18, 19, 20, 21, 22 are shifted to higher frequencies with increasing immersion depth. An evaluation of the position of the second amplitude minima 26, 27, 28, 29, 30 can thus be converted into an output signal 12 giving the level 3 in the course of a calibration by means of the evaluation and control unit 9.

FIG. 4 is used to illustrate the migration of the positions of the second amplitude minima. In FIG. 4 the position of the second amplitude minimum of the frequency spectra 18, 19, 20, 21, 22 is plotted as a function of the immersion depth as curve 31 when the probe electrode 6 is in contact with the medium 4 or is immersed in the medium 4. Here the diamond symbols correspond to measured values, the connecting lines merely relate to the linear interpolation. Accordingly, measurement point 32 on the curve 31 corresponds to the position of the second amplitude minimum 33—which is associated with the ¾λ resonance—of the dry curve 17 according to FIG. 3.

As can be seen, a significant drop in the frequency of the order of magnitude of 100 MHz occurs when the measurement point 34 is observed, which corresponds to the second amplitude minimum 26 in FIG. 3, corresponding to a first contact of the probe electrode 6 of the medium 4. In the further course of the curve 31, a substantially continuous increase in frequency can be identified with increasing immersion depth of the probe electrode 6 in the medium 4.

Approximately at the measurement point 35 corresponding to the amplitude minimum 28 of the curve 20 at 40% immersion depth, the frequency position of the amplitude minimum approximately corresponds to that of the measurement point 32 corresponding to the second amplitude minimum 33 of the dry curve 17 according to FIG. 3.

In order to be able to make an evaluation of the continuous filling level at this measurement point in an unambiguous manner, an evaluation of the evaluation window 23 is always performed as an additional criterion so that confusions are eliminated between the measurement point 32 and the measurement point 35 since the measurement point 32 cannot occur if there is no signal in the evaluation window 23.

As is further illustrated in FIG. 4 with reference to curve 36, the evaluation of the positional shift of the third amplitude minimum of each of the curves 18, 19, 20, 21, 22 can be performed in a similar manner. The curve points 37, 38, 39, 40 here correspond to the third amplitude minima—which are associated with the 5/4λ resonances—of the corresponding curves according to FIG. 3.

As can be seen in FIG. 3, an overlap of the positions of the second amplitude minima of curves having a high insertion depth can be observed with the positions of the third amplitude minima of curves having lower immersion depths. It is possible to distinguish between the second and third amplitude minima in the sense of an unambiguous assignment of a position of an amplitude minimum to an immersion depth if the quality of the amplitude minima is additionally determined and evaluated. This is because FIG. 3 reveals the experimental finding that the quality of the third amplitude minima differs significantly from the quality of the second amplitude minima. Within the framework of the present application, this term is understood both as the manifestation of the minimum with regard to the amplitude and also the width of the minimum. The evaluation of the quality also allows minima to be evaluated within the framework of the invention as a prerequisite for the further evaluation.

In this way, a limit level monitoring and also a continuous level measurement has been proposed by means of the method according to the invention using the device according to the invention.

A frequency sweep is performed for calibrating the device according to the invention and the positions of the amplitude minima are determined in the dry case in order to determine the evaluation window 23 important for the evaluation. Such a calibration can be performed easily at any time and in particular requires no interventions in the apparatus structure. A calibration is always required when the measuring device is to be used with a probe electrode 6 having a different length 15. It is advantageous however that a calibration is not required according to the invention when changes of the medium 4 to be measured are made since the experimentally determined dependence of the measurement quantities on the immersion depth or on the question as to whether the probe electrode 6 contacts the medium 4 has proved to be independent of the medium.

FIG. 5 illustrates a preferred exemplary embodiment of a method according to the invention for detecting a level. As is illustrated in FIG. 5a by means of a schematic circuit diagram, according to this embodiment of the invention, the oscillator 7 is assigned a pulse generator 45 which switches the oscillator 7 on and off in a temporally pulsed manner. To this end, the pulse generator 45 in principle relays rectangular pulses 46 which vary between logic 1 and logic 0 to the oscillator 7. The oscillator 7 can be incorporated in the circuit according to one of the configurations shown in FIGS. 1 and 2. As is indicated by f in FIG. 5a, the oscillator 7 can be operated at variable frequency.

According to a preferred exemplary embodiment of a method according to the invention, a rectangular signal with rectangular pulses 46 is now generated by means of the pulse generator 45, by which means the oscillator 7 can be switched on and off in a pulsed manner. The width of the rectangular pulses 46 is selected so that it comprises a plurality of oscillation periods at the respective frequency f.

In order to scan a frequency spectrum in discrete steps with this method, the frequency f of the oscillator 7 is varied according to the invention from one rectangular pulse 46 to another rectangular pulse 46. In so doing, however, the frequency f is kept constant for the duration of the rectangular pulse 46. The signal delivered by the oscillator 7 in the operating mode described appears in principle as shown schematically in FIG. 5b. FIG. 5b shows the graphs of the time behaviour of the voltage delivered by the oscillator 7. As can be seen, the signal consists of so-called bursts 47, 48, 49. The frequency f within each burst 47, 48, 49 is constant. However, the frequency within the burst 47 differs from that within the burst 48 which in turn differs from that within the burst 49.

### REFERENCE LIST

1 Level measuring device
2 Electrically conducting tank
3 Level
4 Medium
5 Opening
6 Probe electrode
7 Oscillator
8 Amplifier
9 Evaluation and control unit
10 Terminal
11 Terminal/feed point
Zg Internal impedance
Zv Amplifier internal impedance
12 Output signal
13 Deposit build-up
14 Control signal
15 Length
16 Counter-electrode
100 Level measuring device
200 Electrically non-conducting tank
17 Frequency spectrum for non-immersed probe electrode/dry spectrum
18 Frequency spectrum for probe electrode just touching the medium 4
19 Frequency spectrum for probe electrode 20% immersed in the medium
20 Frequency spectrum for probe electrode 40% immersed in the medium
21 Frequency spectrum for probe electrode 60% immersed in the medium
22 Frequency spectrum for probe electrode 80% immersed in the medium
23 Evaluation window
24 First amplitude minimum, dry
25 First amplitude minimum, 0%
26 Second amplitude minimum, 0%
27 Second amplitude minimum, 20%
28 Second amplitude minimum, 40%
29 Second amplitude minimum, 60%
30 Second amplitude minimum, 80%
31 Position of second amplitude minimum with respect to immersion depth
32 Measurement point
33 Second amplitude minimum, dry case
34 Measurement point
35 Measurement point
36 Position of third amplitude minimum with respect to immersion depth
37 Measurement point
38 Measurement point
39 Measurement point
40 Measurement point
41 Third amplitude minimum, 0%
42 Third amplitude minimum, 20%
43 Third amplitude minimum, 40%
44 Third amplitude minimum, 60%
45 Pulse generator
46 Rectangular pulse
47 Burst
48 Burst
49 Burst

1. A device (1) for detecting a level (3) of media (4), preferably in a tank (2, 200), comprising an elongate electrical probe conductor (6) projecting substantially vertically into the tank (2, 200), which can be attached in a manner electrically insulated from said tank, a electrical time-variable generator (7) having an internal impedance (Zg) for connection to a feed point (11) of the probe conductor (6) in order to apply a time-variable voltage to this, wherein the feed point (11) is disposed on one, preferably on the tank-side, end of the probe conductor (6), and an evaluation and/or control unit (9) for evaluating an electrical quantity of the probe conductor (6), characterised in that the evaluation and/or control unit (9) is configured to measure a base impedance of the probe conductor (6) at the feed point (11).

2. The device (1) according to claim 1, characterised in that the generator (7) comprises an electrical oscillator (7) in order to apply an alternating voltage having a pre-definable frequency to the feed point (11).

3. The device (1) according to claim 2, characterised in that the oscillator (7) is configured to generate an alternating voltage with a resonance frequency of the circuit formed from the probe conductor (6), the oscillator (7) and the tank (2, 200) and/or the counter-conductor (16), wherein the evaluation and/or control unit (9) is configured to measure a base impedance of the probe conductor (6) at the feed point (11).

4. The device (1) according to claim 3, characterised in that the oscillator (7) is configured to generate an alternating voltage having a λ/4 frequency, which substantially corresponds to a wavelength which is four times the length extension (15) of the probe conductor (6).

5. The device (1) according to claim 2, characterised in that the oscillator (7) is additionally configured for electrical connection to the tank (2).

6. The device (1) according to claim 1, characterised in that the generator (7) comprises a pulse generator for generating control pulses, wherein the evaluation and/or control unit (9) is configured for the frequency-resolved measurement of the base impedance of the probe conductor (6) at the feed point (11).

7. The device (1) according to claim 1, characterised in that the generator (7) comprises a pulse generator for generating excitation pulses, wherein the excitation pulses have at least one flank increasing to a maximum within a time interval corresponding to the order of magnitude of the reciprocal of a highest frequency to be evaluated.

8. The device (1) according to claim 1, characterised in that in addition to the probe conductor (6), an electrical counter-conductor (16) is provided to form an electrical opposite pole, wherein the oscillator (7) is additionally configured for electrical connection to the counter-conductor (16).

9. The device (1) according to claim 8, characterised in that the counter-conductor (16) is configured to be disposed inside the tank (200), preferably parallel to the probe conductor (6).

10. The device (1) according to claim 8, characterised in that the counter-conductor (16) is configured to be substantially of the same type as the probe conductor (6).

11. The device (1) according to claim 8, characterised in that the counter-conductor (16) is configured as an open strip transmission line.

12. The device (1) according to claim 1, characterised in that the probe conductor (6) is rod-shaped and/or shaped as a cable.

13. The device (1) according to claim 1, characterised in that a variable impedance (Zv) is switched between the evaluation and/or control unit (9) and a circuit formed from the probe conductor (6), the oscillator (7) and the tank (2, 200) and/or the counter-conductor (16).

14. The device (1) according to claim 1, characterised in that means are provided for pulsed triggering of the oscillator (7) and/or for, preferably continuous, variation of the frequency within a frequency interval, wherein the oscillator (7) is preferably configured for generating frequencies in a range around three times and/or five times the λ/4 frequency and/or twice and/or four times the λ/4 frequency.

15. Method for operating a device (1) according to claim 1, characterised in that in order to measure the base impedance the oscillation amplitude is measured at at least one frequency in order to determine the level (3).

16. The method according to claim 15, characterised in that an alternating voltage is generated by means of the generator.

17. The method according to claim 15 characterised in that control pulses are generated by means of the generator (7).

18. The method according to claim 15, characterised in that excitation pulses are generated by means of the generator (7), wherein the excitation pulses have at least one flank increasing to a maximum within a time interval corresponding to the order of magnitude of the reciprocal of a highest frequency to be evaluated.

19. The method according to claim 15, characterised in that the oscillation amplitude is measured at a reference frequency, wherein a signal is generated when exceeding a pre-selected threshold value of the oscillation amplitude.

20. The method according to claim 15, characterised in that the reference frequency is the λ/4 frequency and/or an odd integral multiple of the λ/4 frequency.

21. The method according to claim 15, characterised in that the reference frequency is twice the λ/4 frequency and/or an odd integral multiple of the λ/4 frequency.

22. The method according to claim 15, characterised in that the generator (7) is operated successively at different frequencies, wherein the oscillation amplitude is measured and recorded and that in the frequency spectrum (17, 18, 19, 20, 21, 22) thus determined, the frequency position of at least one amplitude minimum (24, 25, 26, 27, 28, 29, 30, 41, 42) is determined.

23. The method according to claim 15, characterised in that the frequency position of at least one amplitude minimum (24, 25, 26, 27, 28, 29, 30, 41, 42) and/or of at least one amplitude maximum is used to determine the level (3).

24. The method according to claim 15, characterised in that the quality of at least one amplitude minimum (24, 25, 26, 27, 28, 29, 30, 41, 42) is determined in order to make a determination of an appertaining resonance order to determine the level (3).

25. The method according to claim 15, characterised in that the frequency interval includes three times and/or five times the λ/4 frequency.

26. A method for calibrating, in particular after variation of the probe conductor (6), a device (1) according to claim 1, characterised in that a frequency spectrum (17) of the circuit formed from the probe conductor (6), the generator (7) and the tank (2, 200) and/or the counter-conductor (16) is recorded, wherein the probe conductor (6) is not in contact with media (4) during the recording and that the frequency position of at least one amplitude minimum (24, 29) is determined in the frequency spectrum (17).

27. The method for calibrating according to claim 26, characterised in that in order to record the frequency spectrum (17) the generator (7) is successively operated at different frequencies, wherein the oscillation amplitude is measured and recorded.

28. The method for calibrating according to claim 26, characterised in that in order to record the frequency spectrum (17), control pulses are generated by means of the generator (7).

29. The method for calibrating according to claim 26, characterised in that excitation pulses are generated by means of the generator (7), wherein the excitation pulses have at least one flank increasing to a maximum within a time interval corresponding to the order of magnitude of the reciprocal of a highest frequency to be evaluated.

30. Use of a device (1) according to claim 1 for measurement of a level, characterised in that in parallel the same level (3) of the same medium (4) is measured by means of a potentiometric and/or capacitive and/or echo method.
